(19) United States
(12) Patent Application Publication
(10) Pub. No.: US 2025/0015045 A1
(43) Pub. Date: Jan. 9, 2025

(54) METHOD FOR STACKING INTEGRATED CIRCUIT WAFERS AND DIES

(71) Applicant: Tokyo Electron Limited, Tokyo (JP)

(72) Inventors: H. Jim Fulford, Marianna, FL (US); Partha Mukhopadhyay, Oviedo, FL (US); Mark I. Gardner, Austin, TX (US)

(21) Appl. No.: 18/751,859

(22) Filed: Jun. 24, 2024

Related U.S. Application Data
(60) Provisional application No. 63/524,717, filed on Jul. 3, 2023.

(51) Int. Cl. H01L 23/00; H01L 21/304; H01L 21/3065; H01L 21/683; H01L 21/768; H01L 21/78

(52) U.S. Cl. CPC H01L 24/94; H01L 21/304; H01L 21/3065; H01L 21/6835; H01L 21/76898; H01L 21/78; H01L 24/80; H01L 2224/80895; H01L 2224/80896; H01L 2224/94; H01L 2924/1515

(57) ABSTRACT

A method includes receiving a first device wafer comprising a plurality of dies, bonding a first side of a temporary wafer to a first side of the first device wafer to form a combined wafer, and performing a first patterning process on the combined wafer to form first trenches in the combined wafer. The first trenches fully extend through the first device wafer and partially into the temporary wafer from the first side of the temporary wafer. The first trenches separate the plurality of dies from each other. The method further includes placing the combined wafer on a support and applying a force to the combined wafer to separate the temporary wafer into individual temporary regions. Each individual temporary region is bonded to a respective individual die. The method further includes attaching individual dies to a second device wafer and removing the individual temporary regions from the individual dies.

### CROSS-REFERENCE TO RELATED APPLICATIONS

This application claims the benefit of U.S. Provisional Application No. 63/524,717, filed on Jul. 3, 2023, which application is hereby incorporated herein by reference.

### TECHNICAL FIELD

The present invention relates generally to a method for 3D integrated circuit integration, and, in particular embodiments, to a method for stacking integrated circuit wafers and dies.

### BACKGROUND

Transistors per unit area on a chip have been increasing in density over the decades. As two-dimensional (2D) space available for circuit elements begins to exhaust space available, chip fabrication moves to three-dimensional (3D) designs in which transistors and other circuit elements are stacked on top of each other. Monolithic integration includes forming transistors on top of each other on a single wafer (substrate). Heterogeneous integration includes bonding two or more wafers and/or dies together to form vertically stacked devices.

### SUMMARY

In accordance with an embodiment of the present disclosure, a method includes receiving a first device wafer, which comprises a plurality of dies. The method further includes bonding a first side of a temporary wafer to a first side of the first device wafer to form a combined wafer and performing a first patterning process on the combined wafer to form a plurality of first trenches in the combined wafer. The plurality of first trenches fully extend through the first device wafer and partially into the temporary wafer from the first side of the temporary wafer. The plurality of first trenches separate the plurality of dies from each other. The method further includes placing the combined wafer on a support with the temporary wafer being interposed between the support and the first device wafer and applying a force to the combined wafer to separate the temporary wafer into individual temporary regions. Each individual temporary region is bonded to a respective individual die. The method further includes attaching individual dies to a second device wafer and removing the individual temporary regions from the individual dies. In an embodiment, the first patterning process includes a laser etching process, a plasma etching process, or a mechanical dicing process. In an embodiment, the temporary wafer includes a quartz wafer or a semiconductor wafer. In an embodiment, the plurality of first trenches are formed in scribe lines of the first device wafer. In an embodiment, the method further includes, before placing the combined wafer on the support, performing a second patterning process on the combined wafer to form a plurality of second trenches in the combined wafer, the plurality of second trenches partially extending into the temporary wafer from a second side of the temporary wafer, the plurality of second trenches being vertically aligned with the plurality of first trenches. In an embodiment, the second patterning process includes a plasma etching process. In an embodiment, the first side of the temporary wafer is bonded to the first side of the first device wafer using a temporary bonding layer, and removing the individual temporary regions from the individual dies includes subjecting the temporary bonding layer to a radiation.

In accordance with another embodiment of the present disclosure, a method includes receiving a first device wafer. The first device wafer includes a plurality of dies separated by scribe lines. The method further includes bonding a first side of a temporary wafer to a first side of the first device wafer using a temporary bonding layer to form a combined wafer and thinning a second side of the first device wafer. The second side of the first device wafer is opposite to the first side of the first device wafer. The method further includes depositing a first protective coating on the second side of the first device wafer and performing a first patterning process on the combined wafer to form a plurality of first trenches in the combined wafer. The plurality of first trenches fully extending through the first protective coating and the first device wafer, and partially into the temporary wafer from the first side of the temporary wafer. The plurality of first trenches are formed in the scribe lines. The method further includes placing the combined wafer on a support with the temporary wafer being interposed between the support and the first device wafer and applying a force to the combined wafer to mechanically separate the temporary wafer into individual temporary regions. Each individual temporary region is bonded to a respective individual die. The method further includes bonding individual dies to a second device wafer and de-bonding the individual temporary regions from the individual dies. In an embodiment, de-bonding the individual temporary regions from the individual dies includes subjecting the temporary bonding layer to an electromagnetic radiation. In an embodiment, the first patterning process includes a laser etching process, a plasma etching process, or a mechanical dicing process. In an embodiment, the temporary wafer includes a quartz wafer or a semiconductor wafer. In an embodiment, before placing the combined wafer on the support, the method further includes: depositing a second protective coating on a second side of the temporary wafer, where the second side of the temporary wafer is opposite to the first side of the temporary wafer; and performing a second patterning process on the combined wafer to form a plurality of second trenches in the combined wafer, the plurality of second trenches fully extending through the second protective coating and partially into the temporary wafer from the second side of the temporary wafer, the plurality of second trenches being vertically aligned with the plurality of first trenches. In an embodiment, the second patterning process includes a plasma etching process. In an embodiment, bonding the individual dies to the second device wafer includes direct bonding the individual dies to the second device wafer.

In accordance with yet another embodiment of the present disclosure, a method includes receiving a first device wafer. The first device wafer includes a plurality of dies separated by scribe lines. The method further includes bonding a first side of a temporary wafer to a first side of the first device wafer using a temporary bonding layer to form a combined wafer, reducing a thickness of the first device wafer, and depositing a first protective coating on a second side of the first device wafer. The second side of the first device wafer is opposite to the first side of the first device wafer. The method further includes forming a plurality of first trenches in the scribe lines of the first device wafer. The plurality of first trenches fully extend through the first protective coating and the first device wafer, and separate the plurality of dies from each other. The method further includes partially extending the plurality of first trenches into the temporary wafer and depositing a second protective coating on a second side of the temporary wafer. The second side of the temporary wafer is opposite to the first side of the temporary wafer. The method further includes forming a plurality of second trenches in the temporary wafer. The plurality of second trenches fully extend through the second protective coating and partially into the temporary wafer from the second side of the temporary wafer. The plurality of second trenches being vertically aligned with the plurality of first trenches. The method further includes placing the combined wafer on a support with the temporary wafer being interposed between the support and the first device wafer and applying a force to the combined wafer to separate the temporary wafer into individual temporary regions. Each individual temporary region is bonded to a respective individual die. The method further includes bonding individual dies to a second device wafer, and de-bonding the individual temporary regions from the individual dies. In an embodiment, de-bonding the individual temporary regions from the individual dies includes subjecting the temporary bonding layer to a laser radiation. In an embodiment, forming the plurality of first trenches includes a laser etching process, a plasma etching process, or a mechanical dicing process. In an embodiment, the temporary wafer includes a quartz wafer or a semiconductor wafer. In an embodiment, forming the plurality of second trenches includes a plasma etching process. In an embodiment, bonding the individual dies to the second device wafer includes direct bonding the individual dies to the second device wafer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1O illustrate cross-sectional views of different stages of a method for forming a stacked integrated circuit in accordance with various embodiments;

FIGS. 2A-2I illustrate cross-sectional views of different stages of a method for forming a stacked integrated circuit in accordance with various embodiments; and

FIG. 3 illustrates a flow diagram of a method for forming a stacked integrated circuit in accordance with various embodiments.

### DETAILED DESCRIPTION OF ILLUSTRATIVE EMBODIMENTS

The making and using of various embodiments are discussed in detail below. It should be appreciated, however, that the various embodiments described herein are applicable in a wide variety of specific contexts. The specific embodiments discussed are merely illustrative of specific ways to make and use various embodiments, and should not be construed in a limited scope.

Techniques described herein include a three-dimensional (3D) die attachment method with a disposable underlayer (e.g., quartz or semiconductor wafer). By having a quartz wafer (or semiconductor wafer) attached to one side of a device wafer, the device wafer be thinned to a desired thickness (i.e. less than 50 μm). The quartz wafer (or semiconductor wafer) allows the device wafer to be processed as a single wafer through multiple process steps and diced at the end of the process sequence. The disclosed process may be also applied to a stack of multiple wafers. The dies obtained as a result of dicing the device wafer may be bonded to another device wafer.

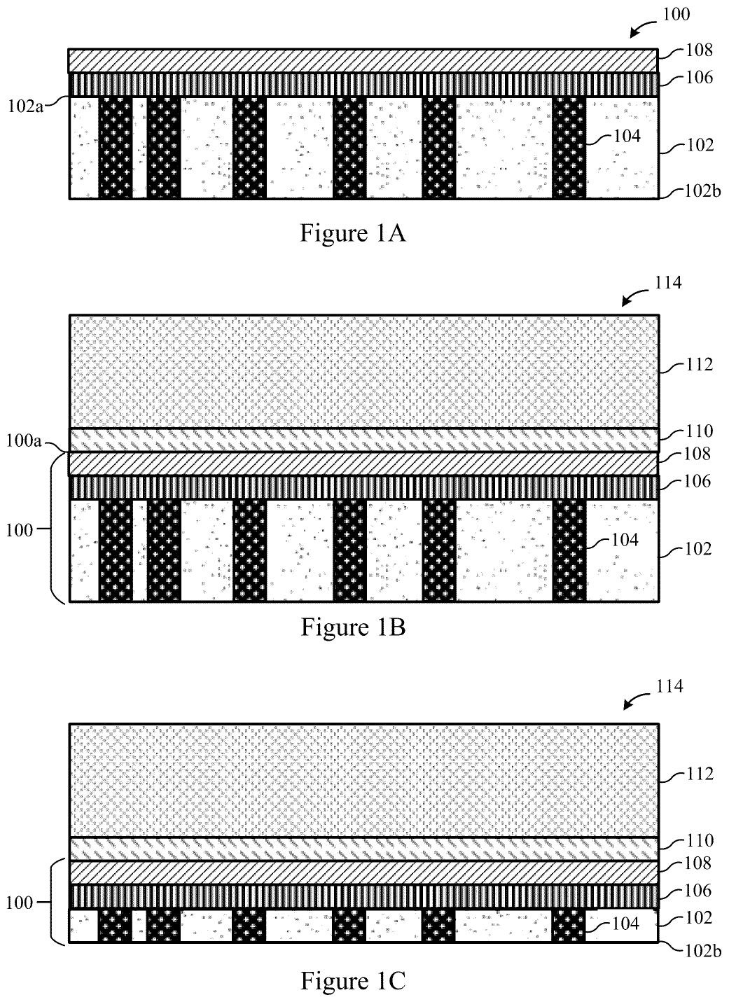

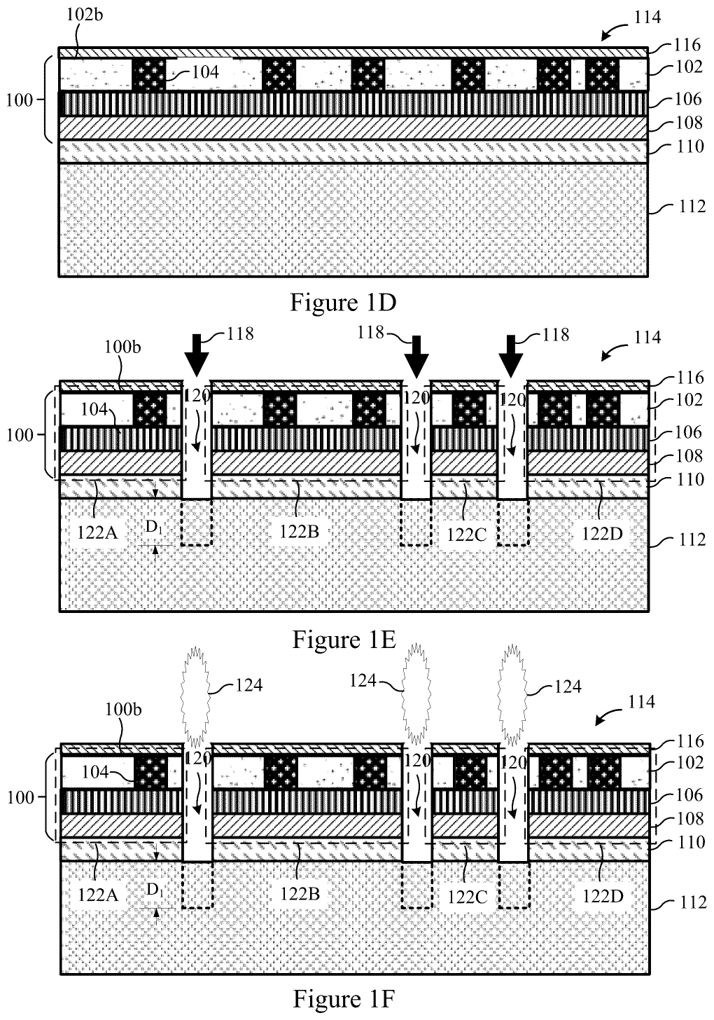

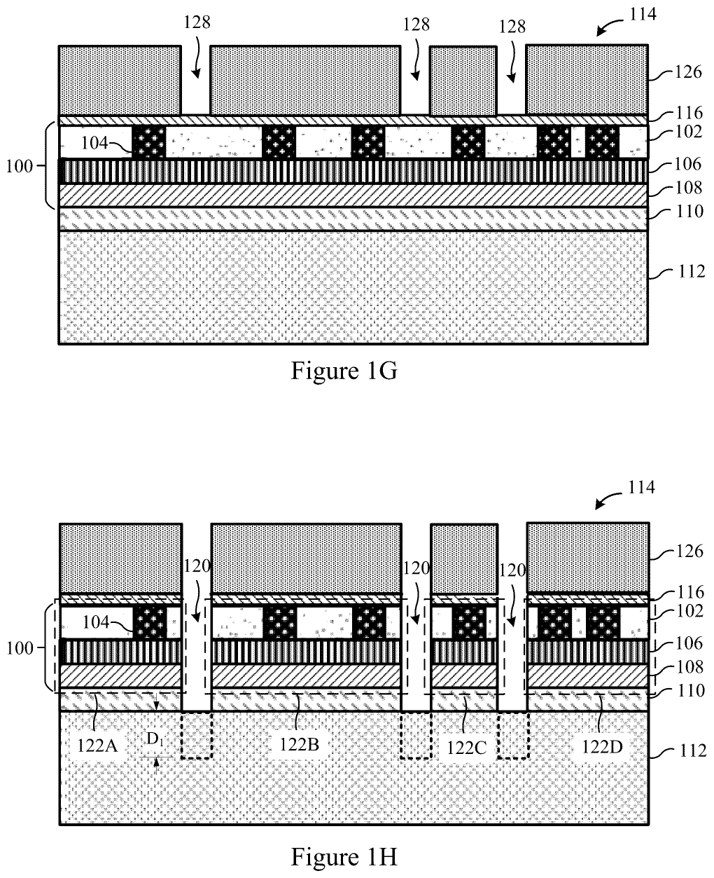

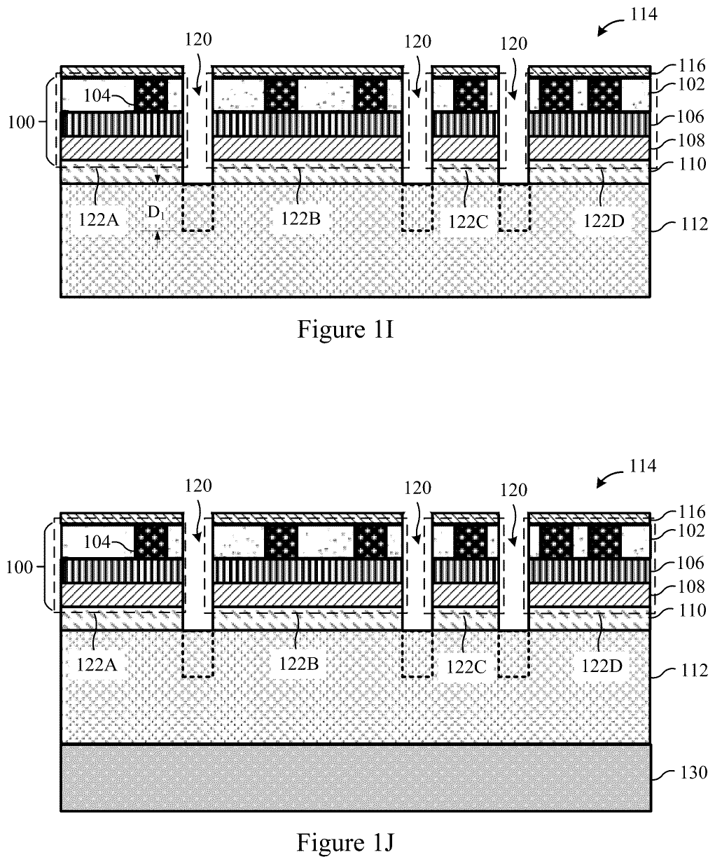

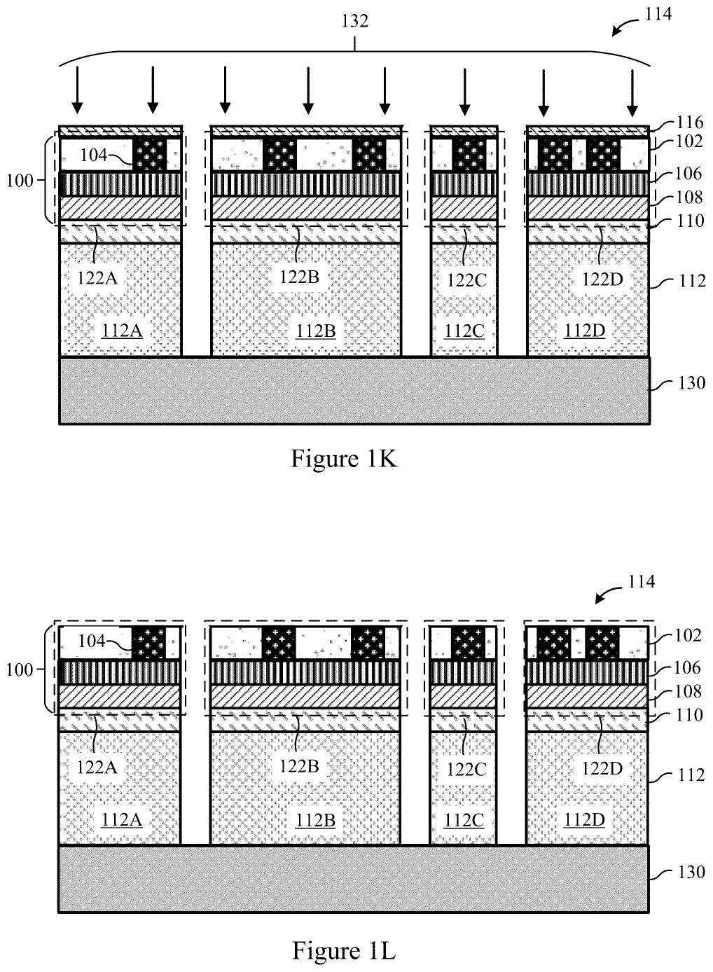

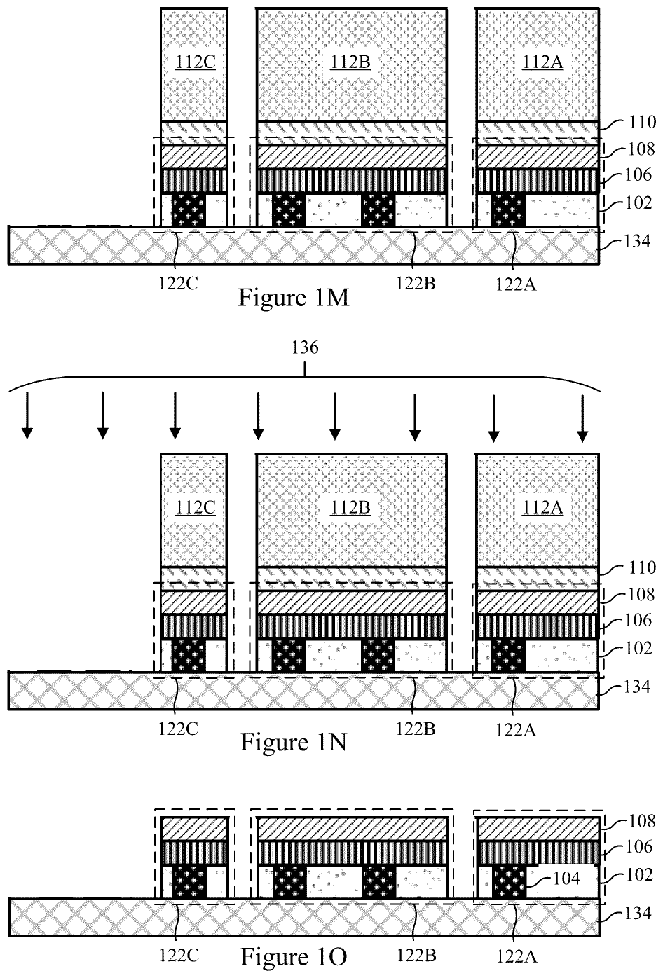

FIGS. 1A-1O illustrate cross-sectional views of different stages of a method for forming a stacked integrated circuit in accordance with various embodiments. Referring to FIG. 1A, an integrated circuit wafer 100 is formed. The integrated circuit wafer 100 comprises a plurality of die or chip regions that are separated by scribe lines, singulation lanes, or dicing streets. Each of the die regions may include one or more integrated circuits. As described below in greater detail, the integrated circuit wafer 100 is singulated or diced to form a plurality of individual dies or chips. The individual dies are subsequently attached to an integrated circuit wafer 134 (see FIG. 1O) to form the stacked integrated circuit.

The integrated circuit wafer 100 may comprise a substrate 102. The substrate 102 may comprise layers of semiconductors suitable for various microelectronics. In one or more embodiments, the substrate 102 may be a silicon wafer, or a silicon-on-insulator (SOI) wafer. In certain embodiments, the substrate 102 may comprise a silicon germanium wafer, silicon carbide wafer, gallium arsenide wafer, gallium nitride wafer, or other compound semiconductors. In other embodiments, the substrate 102 may comprise heterogeneous layers such as silicon germanium on silicon, gallium nitride on silicon, silicon carbon on silicon, or layers of silicon on a silicon or SOI substrate.

A device layer 106 is formed over a first side 102a of the substrate 102. The device layer may comprise devices (e.g., transistors, diodes, resistors, capacitors, inductors, etc.) that are integrated into integrated circuits (e.g., microprocessor, memory, etc.). The devices may be formed in any suitable manner, including using any suitable combination of implantation, wet and/or dry deposition, photolithography and etch techniques.

An interconnect structure 108 is formed over the device layer 106. The interconnect structure 108 comprises conductive wirings that are configured to interconnect devices of the device layer 106. In some embodiments, the interconnect structure 108 comprises a plurality of metallization layers (not individually shown) embedded in a plurality of dielectric layers (not individually shown). The dielectric layers may comprise silicon oxide, low-k dielectric materials, or the like. The dielectric layers may be deposited using suitable deposition processes. Suitable deposition processes may include a spin-on coating process, a chemical vapor deposition (CVD) process, an atomic layer deposition (ALD) process, plasma deposition processes (e.g., a plasma-enhanced CVD (PECVD) process, or a plasma-enhanced ALD (PEALD) process), and/or other deposition processes or combinations of processes. The metallization layers comprise conductive lines and vias made of conductive materials such aluminum, copper, or the like. The conductive lines and vias may be formed using a damascene process, a dual damascene process, or the like. In some embodiments, the interconnect structure 108 is formed such that the scribe lines of the integrated circuit wafer 100 are free of conductive wirings. In other embodiments, the interconnect structure 108 is formed such that some conductive wirings are formed in the scribe lines of the integrated circuit wafer 100.

In some embodiments, a plurality of through-silicon vias (TSVs) 104 are formed in the substrate 102. The TSVs 104 may comprise a conductive material such copper, for example. In some embodiments, the TSVs 104 further comprise liners (not shown) that electrically isolate the conductive material of the TSVs 104 from the substrate 102. The liners may comprise suitable insulating materials.

Referring to FIG. 1B, a temporary wafer 112 is bonded to the integrated circuit wafer 100 to form a combined wafer 114. In some embodiments, the bonding process comprises depositing a temporary bonding layer 110 on a first side 110a of the integrated circuit wafer 100 or on the temporary wafer 112, bringing the integrated circuit wafer 100 and the temporary wafer 112 in physical contact, and performing an anneal process strengthen a bond between the integrated circuit wafer 100 and the temporary wafer 112. The temporary bonding layer 110 may comprise one or more metallic materials, one or more dielectric materials, one or more epoxy materials, a combination thereof, or the like. The anneal process may comprise a UV annealing process, a thermal annealing process, a plasma annealing process, or the like. In some embodiments, the temporary wafer 112 may comprise quartz. In other embodiments, the temporary wafer 112 may be a semiconductor wafer. In such embodiments, the temporary wafer 112 may be similar to the substrate 102, and the description is not repeated herein.

Referring to FIG. 1C, a thickness of the integrated circuit wafer 100 is reduced. In some embodiments, the thickness of the integrated circuit wafer 100 is reduced by reducing a thickness of the substrate 102. The thickness of the substrate 102 may be reduced by performing a thinning process on a second side 102b of the substrate 102. The thinning process may comprise a mechanical grinding process, a chemical mechanical polishing (CMP) process, an etch process, a combination thereof, or the like. In some embodiments, after performing the thinning process, the thickness of the integrated circuit wafer 100 is in a range from 5 μm to 100 μm.

Referring to FIG. 1D, the combined wafer 114 is flipped over and a protective coating 116 is formed on the second side 102b of the substrate 102. The protective coating 116 may comprise a suitable dielectric material, a polymer material, or the like. The protective coating 116 may be formed using suitable deposition processes, such as a spin-on coating process, a CVD process, an ALD process, plasma deposition processes (e.g., a PECVD process, or a PEALD process), and/or other deposition processes or combinations of processes. In some embodiments, a thickness of the protective coating 116 is in a range from 25 Å to 300 Å. This protective coating 116 may be configured to protect the underlying integrated circuit wafer 100 and reduce or eliminate defects from being deposited on the integrated circuit wafer 100 during subsequent steps, such as a singulation process, for example.

After forming the protective coating 116, a partial singulation or dicing process is performed on the combined wafer 114. In some embodiments, the partial singulation or dicing process is performed using a first method described below with reference to FIG. 1E. In other embodiments, the partial singulation or dicing process is performed using a second method described below with reference to FIG. 1F. In yet other embodiments, the partial singulation or dicing process is performed using a third method described below with reference to FIGS. 1G-1I. In yet other embodiments, the partial singulation or dicing process is performed using a combination of the first method, the second method, and the third method.

Referring to FIG. 1E, the partial singulation or dicing process is performed on the combined wafer 114 using a laser beam etch process. In some embodiments, a laser beam 118 scans the second side 100b of the integrated circuit wafer 100 and forms trenches 120 in the scribe lines of the integrated circuit wafer 100. In some embodiments, the trenches 120 extend through the protective coating 116, the integrated circuit wafer 100, the temporary bonding layer 110, and expose the temporary wafer 112. In other embodiments, the trenches 120 extend through the protective coating 116, the integrated circuit wafer 100, the temporary bonding layer 110, and partially into the temporary wafer 112. In such embodiments, the trenches 120 extend into the temporary wafer 112 to a depth D₁ in a range from 50 Å to 1000 Å. The trenches 120 separate die regions (e.g., die regions 122A-122D) of the integrated circuit wafer 100.

Referring to FIG. 1F, the partial singulation or dicing process is performed on the combined wafer 114 using a mechanical dicing process. In some embodiments, a saw 124 is used to form trenches 120 in the scribe lines of the integrated circuit wafer 100. In some embodiments, the trenches 120 extend through the protective coating 116, the integrated circuit wafer 100, the temporary bonding layer 110, and expose the temporary wafer 112. In other embodiments, the trenches 120 extend through the protective coating 116, the integrated circuit wafer 100, the temporary bonding layer 110, and partially into the temporary wafer 112. In such embodiments, the trenches 120 extend into the temporary wafer 112 to the depth D₁. The trenches 120 separate die regions (e.g., die regions 122A-122D) of the integrated circuit wafer 100.

Referring to FIGS. 1G-1I, the partial singulation or dicing process is performed on the combined wafer 114 using an etch process. Referring to FIG. 1G, a photoresist layer 126 is formed over the protective coating 116. The photoresist layer 126 may comprise a positive-tone photoresist or a negative-tone photoresist. The photoresist layer 126 may be deposited on protective coating 116 in any suitable manner. For example, the photoresist layer 126 may be deposited by spin-coating, spray-coating, dip-coating, or roll-coating. In other embodiments, the photoresist layer 126 may be deposited using a CVD process, a PECVD process, an ALD process, or other suitable processes. In various embodiments, the photoresist layer 126 may comprise an agent-generating ingredient that, in response to a suitable agent-activation trigger (e.g., heat or radiation), generates a solubility-changing agent (e.g., an acid). Example agent-generating ingredients may include a thermal-acid generator (TAG) that is configured to generate an acid in response to heat or a photo-acid generator (PAG) that is configured to generate an acid in response to actinic radiation.

After forming the photoresist layer 126, a reticle (not shown) is disposed over the photoresist layer 126. The reticle may be used to modulate a dose (or an intensity) of a radiation (e.g., actinic radiation) that is used to expose the photoresist layer 126. In such embodiments, the reticle may comprise regions of different transparency to the radiation (e.g., opaque and transparent regions). The photoresist layer 126 is then subject to an exposure step through the reticle. The radiation exposes exposed regions of the photoresist layer 126 while unexposed (or unmodified) regions of the photoresist layer 126 are protected by the reticle. The exposure step may be performed using a photolithographic technique such as dry lithography (e.g., using 193 dry lithography), immersion lithography (e.g., using 193 nanometer immersion lithography), i-line lithography (e.g., using 365 nanometer wavelength UV radiation for exposure), H-line lithography (e.g., using 405 nanometer wavelength UV radiation for exposure), extreme UV (EUV) lithography, deep UV (DUV) lithography, or any suitable photolithography technology.

In some embodiments, the radiation generates an acid in the exposed regions of the photoresist layer 126. The acid may be generated from the PAG that is present in the photoresist layer 126 under the influence of the radiation. The acid may react with the material of the photoresist layer 126 and alter the solubility of the exposed regions of the photoresist layer 126. Subsequently, the exposed regions of the photoresist layer 126 are removed by performing a developing process using a suitable developer to form openings 128 in the photoresist layer 126. In some embodiments, the openings 128 are formed over and expose the scribe lines of the integrated circuit wafer 100.

Referring to FIG. 1H, the etch process is performed on the combined wafer 114 while using the photoresist layer 126 as an etch mask. The etch process may comprise a plasma etch process, such as a reactive ion etch process, for example. In some embodiments, the etch process may be performed using a plurality of etchants that are selective to etched materials of the combined wafer 114. The etch process forms trenches 120 in the scribe lines of the integrated circuit wafer 100. In some embodiments, the trenches 120 extend through the protective coating 116, the integrated circuit wafer 100, the temporary bonding layer 110, and expose the temporary wafer 112. In other embodiments, the trenches 120 extend through the protective coating 116, the integrated circuit wafer 100, the temporary bonding layer 110, and partially into the temporary wafer 112. In such embodiments, the trenches 120 extend into the temporary wafer 112 to the depth D₁. The trenches 120 separate die regions (e.g., die regions 122A-122D) of the integrated circuit wafer 100.

Referring to FIG. 1I, the photoresist layer 126 (see FIG. 1H) is removed to expose the protective coating 116. In some embodiments, the photoresist layer 126 is removed by ashing followed by a wet clean process.

Referring to FIG. 1J, the combined wafer 114 is attached to a support 130, such that, the temporary wafer 112 is in physical contact with the support 130. In some embodiments, the support 130 may be a dicing tape or any suitable support.

Referring to FIG. 1K, the combined wafer 114 is fully singualted. In some embodiments, a force 132 is applied to the combined wafer 114 to separate the temporary wafer 112 into individual temporary regions (e.g., temporary regions 112A-112D) that are bonded to respective individual dies (e.g., dies 122A-122D). The force 132 mechanically separates (or breaks) the temporary wafer 112 into the individual temporary regions (e.g., temporary regions 112A-112D). In some embodiments, the force 132 is in a range from 0.25 pound-force to 1 pound-force. As surface of the support 130 that is in physical contact with the temporary wafer 112 may have a curvature, bumps, or other topographical features to assist with the full singulation.

Referring to FIG. 1L, portions of the protective coating 116 (see FIG. 1K) are removed from respective individual dies (e.g., dies 122A-122D). The removal process may comprise a mechanical grinding process, a CMP process, an etch process, or the like. The etch process may be performed using wet or dry etchants that are selective to the material of protective coating 116.

Referring to FIG. 1M, some or all of the individual dies (e.g., dies 122A-122D) with temporary regions (e.g., temporary regions 112A-112D) attached thereon are picked up from the support 130 (see FIG. 1L), flipped over and placed to an integrated circuit wafer 134 using a pick-and-place apparatus, for example. In the illustrated embodiment, the individual dies 122A-122C with the temporary regions 112A-112C attached thereon are attached to the integrated circuit wafer 134. The integrated circuit wafer 134 may be similar to the integrated circuit wafer 100 described above with reference to FIG. 1A, and the description is not repeater herein. In some embodiments, the individual dies 122A-122C may be direct bonded to the integrated circuit wafer 134. In such embodiments, the TSVs 104 of the individual dies 122A-122C are electrically and mechanically coupled to conductive features (not shown) of the integrated circuit wafer 134. In other embodiments, the individual dies 122A-122C may be attached to the integrated circuit wafer 134 using connectors (e.g., solder balls) that are formed on the individual dies 122A-122C and/or the integrated circuit wafer 134. In such embodiments, the connectors electrically and mechanically couple the TSVs 104 of the individual dies 122A-122C to conductive features (not shown) of the integrated circuit wafer 134.

Referring to FIG. 1N, a bonding ability of the temporary bonding layer 110 is reduced to facilitate the removal of the temporary regions 112A-112C from the individual dies 122A-122C, respectively. In some embodiments, the bonding ability of the temporary bonding layer 110 may be reduced by subjecting the temporary bonding layer 110 to a radiation 136 (e.g., electromagnetic radiation). The radiation 136 propagates through the temporary regions 112A-112C to reach the temporary bonding layer 110. In some embodiments, the radiation 136 may be a laser beam that scans the temporary regions 112A-112C.

Referring to FIG. 1O, the temporary regions 112A-112C (see FIG. 1N) are removed from the individual dies 122A-122C, respectively. Subsequently, any residual portions of the temporary bonding layer 110 are removed. The removal process may comprise an etch process performed using wet or dry etchants that are selective to the material of the temporary bonding layer 110.

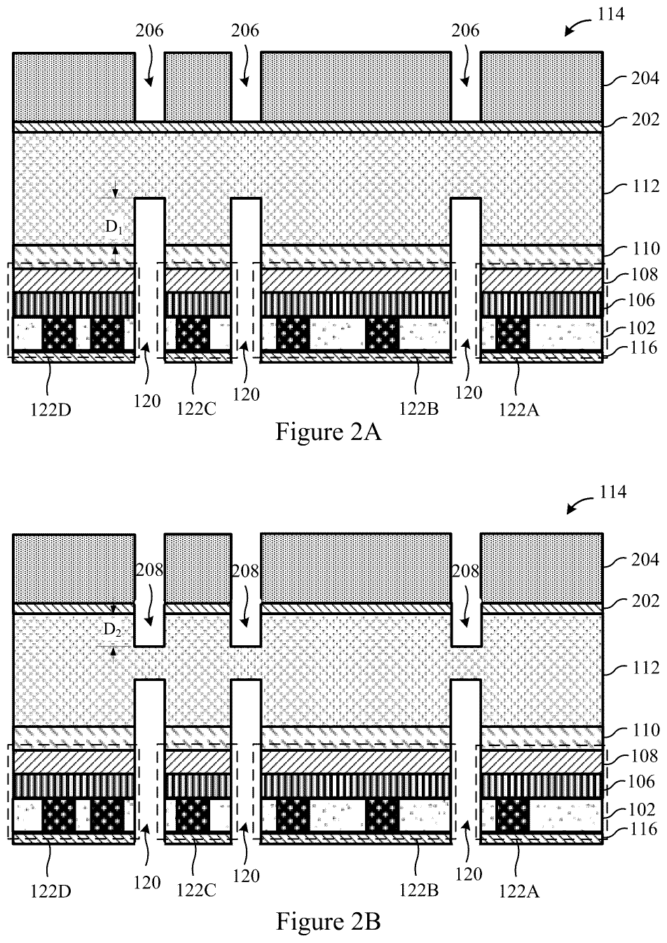

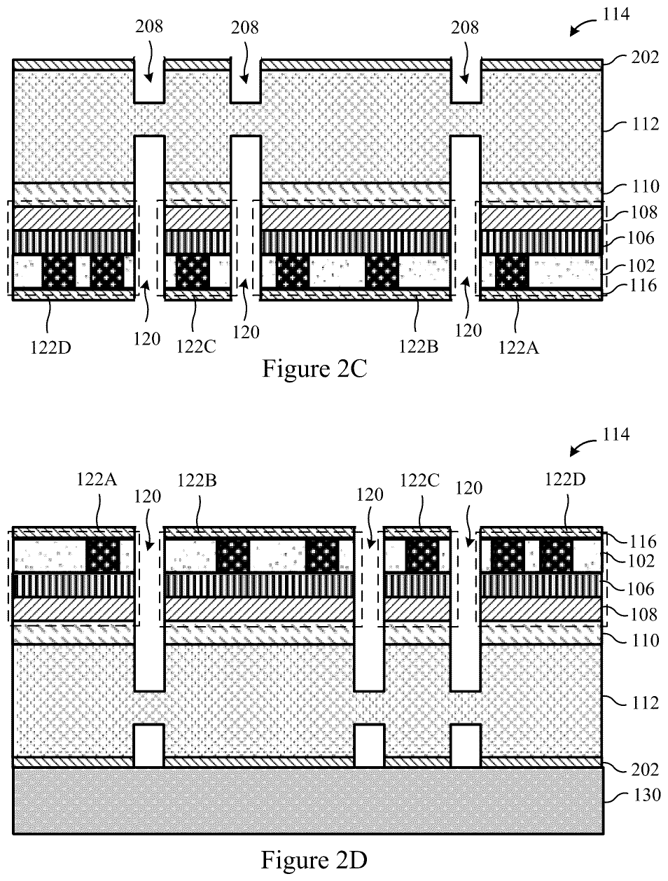

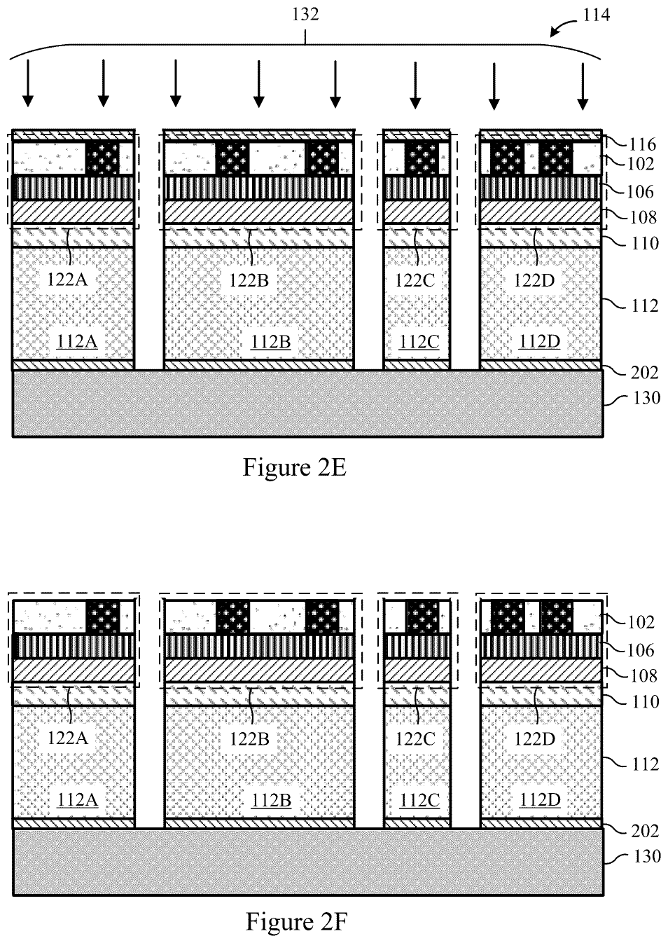

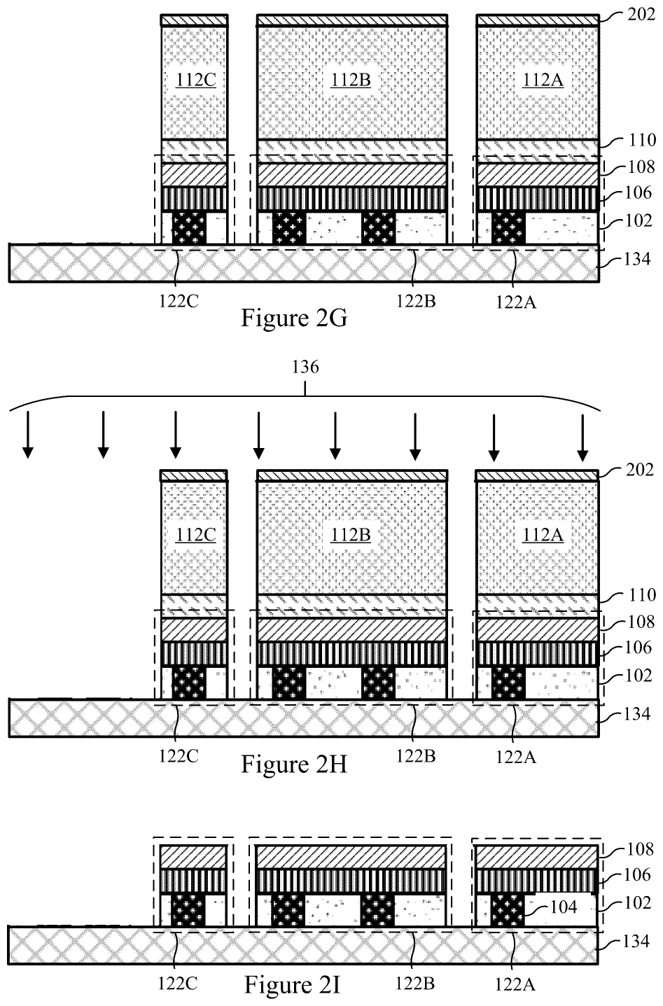

FIGS. 2A-2I illustrate cross-sectional views of different stages of a method for forming a stacked integrated circuit in accordance with various embodiments. The method starts with forming a partially diced combined wafer 114 of FIG. 1I. In some embodiments, the partially diced combined wafer 114 of FIG. 1I may be formed using a first method described above with reference to FIG. 1E. In other embodiments, the partially diced combined wafer 114 of FIG. 1I may be formed using a second method described above with reference to FIG. 1F. In yet other embodiments, the partially diced combined wafer 114 of FIG. 1I may be formed using a third method described above with reference to FIGS. 1G-1I. In yet other embodiments, the partially diced combined wafer 114 of FIG. 1I may be formed using a combination of the first method, the second method, and the third method.

Referring to FIG. 2A, the partially diced combined wafer 114 of FIG. 1I is flipped over and a protective coating 202 is formed on the temporary wafer 112. The protective coating 202 may be formed using similar materials and methods as the protective coating 116 described above with reference to FIG. 1D, and the description is not repeated herein. In some embodiments, the protective coatings 116 and 202 comprise a same material. In other embodiments, the protective coatings 116 and 202 comprise different materials. In some embodiments, the protective coating 202 has a thickness is in a range from 25 Å to 500 Å.

Subsequently, a photoresist layer 204 is formed over the protective coating 202. The photoresist layer 204 may be formed using similar materials and methods as the photoresist layer 126 described above with reference to FIG. 1G, and the description is not repeated herein. The photoresist layer 204 is patterned to form openings 206 therein. The patterning process may be performed as described above with reference to FIG. 1G, and the description is not repeated herein. The openings 206 expose the protective coating 202. In some embodiments, each of the openings 206 is vertically aligned to a respective one of the trenches 120.

Referring to FIG. 2B, an etch process is performed on the protective coating 202 and the temporary wafer 112 while using the photoresist layer 204 as an etch mask. The etch process may comprise a plasma etch process, such as a reactive ion etch process, for example. The etch process may comprise a first etch process that is selective to the material of the protective coating 202 and a second etch process that is selective to the material of the temporary wafer 112. The etch process forms trenches 208 in the temporary wafer 112. In some embodiments, the trenches 208 extend through the protective coating 202 and extend into the temporary wafer 112. The trenches 208 extend into the temporary wafer 112 to the depth D₂. The depth D₂ may be in a range from 500 Å to 10 μm. In some embodiments, each of the trenches 208 is vertically aligned to a respective one of the trenches 120.

Referring to FIG. 2C, the photoresist layer 204 (see FIG. 2B) is removed to expose the protective coating 202. In some embodiments, the photoresist layer 204 is removed by ashing followed by a wet clean process.

Referring to FIG. 2D, the partially singulated combined wafer 114 is attached to a support 130, such that the protective coating 202 is in physical contact with the support 130. In some embodiments, the support 130 may be a dicing tape or any suitable support.

Referring to FIG. 2E, the partially singulated combined wafer 114 is fully singulated. In some embodiments, a force 132 is applied to the partially singulated combined wafer 114 to separate the temporary wafer 112 into individual temporary regions (e.g., temporary regions 112A-112D) that are bonded to respective individual dies (e.g., dies 122A-122D). The force 132 mechanically separates (or breaks) the temporary wafer 112 into the individual temporary regions (e.g., temporary regions 112A-112D). In some embodiments, the force 132 is in a range from 0.1 pound-force to 1 pound-force. As surface of the support 130 that is in physical contact with the protective coating 202 may have a curvature, bumps, or other topographical features to assist with the full singulation.

Referring to FIG. 2F, portions of the protective coating 116 (see FIG. 2E) are removed from respective individual dies (e.g., dies 122A-122D). The removal process may comprise a mechanical grinding process, a CMP process, an etch process, or the like. The etch process may be performed using wet or dry etchants that are selective to the material of the protective coating 116.

Referring to FIG. 2G, some or all of the individual dies (e.g., dies 122A-122D) with temporary regions (e.g., temporary regions 112A-112D) attached thereon are picked up from the support 130 (see FIG. 2F), flipped over and placed to an integrated circuit wafer 134 using a pick-and-place apparatus, for example. In the illustrated embodiment, the individual dies 122A-122C with the temporary regions 112A-112C attached thereon are attached to the integrated circuit wafer 134. The integrated circuit wafer 134 may be similar to the integrated circuit wafer 100 described above with reference to FIG. 1A, and the description is not repeater herein. In some embodiments, the individual dies 122A-122C may be direct bonded to the integrated circuit wafer 134. In such embodiments, the TSVs 104 of the individual dies 122A-122C are electrically and mechanically coupled to conductive features (not shown) of the integrated circuit wafer 134. In other embodiments, the individual dies 122A-122C may be attached to the integrated circuit wafer 134 using connectors (e.g., solder balls) that are formed on the individual dies 122A-122C and/or the integrated circuit wafer 134. In such embodiments, the connectors electrically and mechanically couple the TSVs 104 of the individual dies 122A-122C to conductive features (not shown) of the integrated circuit wafer 134.

Referring to FIG. 2H, a bonding ability of the temporary bonding layer 110 is reduced to facilitate the removal of the temporary regions 112A-112C from the individual dies 122A-122C, respectively. In some embodiments, the bonding ability of the temporary bonding layer 110 may be reduced by subjecting the temporary bonding layer 110 to a radiation 136 (e.g., electromagnetic radiation). The radiation 136 propagates through the protective coating 202 and the temporary regions 112A-112C to reach the temporary bonding layer 110. In some embodiments, the radiation 136 may be a laser beam that scans the temporary regions 112A-112C.

Referring to FIG. 2I, the temporary regions 112A-112C (see FIG. 2H) are removed from the individual dies 122A-122C, respectively. Subsequently, any residual portions of the temporary bonding layer 110 are removed. The removal process may comprise an etch process performed using wet or dry etchants that are selective to the material of the temporary bonding layer 110.

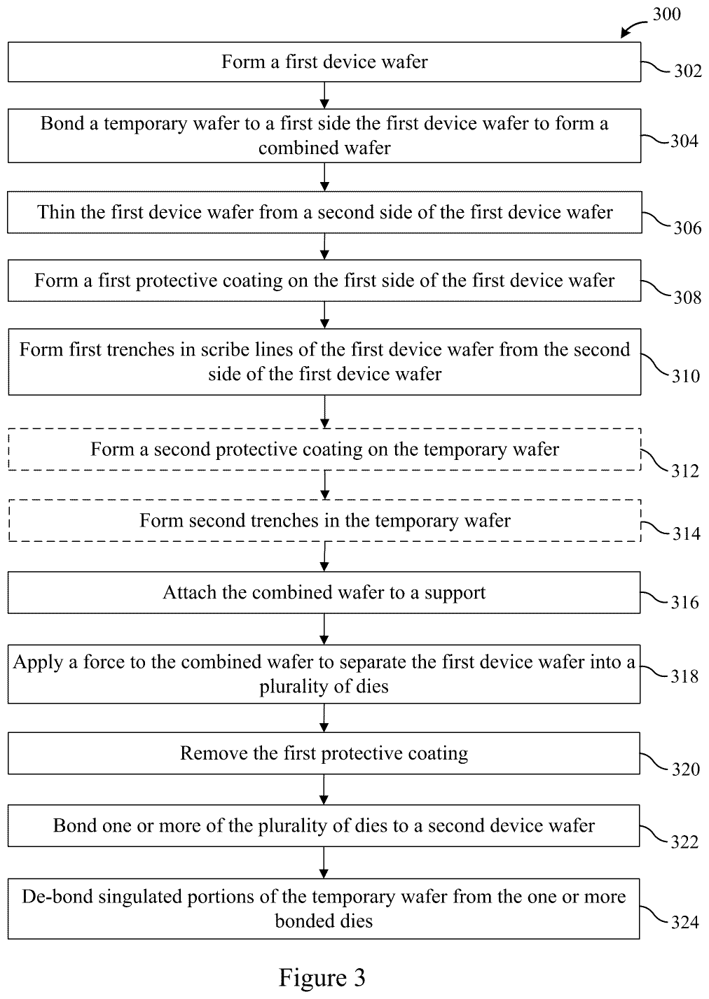

FIG. 3 illustrates a flow diagram of a method 300 for forming a stacked integrated circuit in accordance with various embodiments. The method 300 starts with step 302. In step 302, a first device wafer (e.g., integrated circuit wafer 100 of FIG. 1A) is formed as described above with reference to FIG. 1A. In step 304, a temporary wafer (e.g., temporary wafer 112 of FIG. 1B) is bonded to a first side the first device wafer (e.g., integrated circuit wafer 100 of FIG. 1B) to form a combined wafer (e.g., combined wafer 114 of FIG. 1B) as described above with reference to FIG. 1B.

In step 306, the first device wafer (e.g., integrated circuit wafer 100 of FIG. 1C) is thinned from a second side of the first device wafer (e.g., integrated circuit wafer 100 of FIG. 1C) as described above with reference to FIG. 1C. In step 308, a first protective coating (e.g., protective coating 116 of FIG. 1D) is formed on the first side of the first device wafer (e.g., integrated circuit wafer 100 of FIG. 1D) as described above with reference to FIG. 1D.

In step 310, in some embodiments, first trenches (e.g., trenches 120 of FIG. 1E) are formed in scribe lanes of the first device wafer (e.g., integrated circuit wafer 100 of FIG. 1E) from the second side of the first device wafer (e.g., integrated circuit wafer 100 of FIG. 1E) as described above with reference to FIG. 1E. In other embodiments, first trenches (e.g., trenches 120 of FIG. 1F) are formed in scribe lanes of the first device wafer (e.g., integrated circuit wafer 100 of FIG. 1F) from the second side of the first device wafer (e.g., integrated circuit wafer 100 of FIG. 1F) as described above with reference to FIG. 1F. In yet other embodiments, first trenches (e.g., trenches 120 of FIG. 1I) are formed in scribe lanes of the first device wafer (e.g., integrated circuit wafer 100 of FIG. 1I) from the second side of the first device wafer (e.g., integrated circuit wafer 100 of FIG. 1I) as described above with reference to FIGS. 1G-1I.

In step 312, a second protective coating (e.g., protective coating 202 of FIG. 2A) is formed on the temporary wafer (e.g., temporary wafer 112 of FIG. 2A) as described above with reference to FIG. 2A. In step 314, second trenches (e.g., trenches 208 of FIG. 2C) are formed in the temporary wafer (e.g., temporary wafer 112 of FIG. 2C) as described above with reference to FIGS. 2B and 2C. In some embodiments, steps 312 and 314 may be omitted.

In step 316, in some embodiments when steps 312 and 314 are omitted, the combined wafer (e.g., combined wafer 114 of FIG. 1J) is attached to a support (e.g., support 130 of FIG. 1J) as described above with reference to FIG. 1J. In some embodiments when steps 312 and 314 are performed, the combined wafer (e.g., combined wafer 114 of FIG. 2D) is attached to a support (e.g., support 130 of FIG. 2D) as described above with reference to FIG. 2D.

In step 318, in some embodiments when steps 312 and 314 are omitted, a force (e.g., force 132 of FIG. 1K) is applied to the combined wafer (e.g., combined wafer 114 of FIG. 1K) to separate the first device wafer (e.g., integrated circuit wafer 100 of FIG. 1K) into a plurality of dies (e.g., dies 122A-122D of FIG. 1K) as described above with reference to FIG. 1K. In some embodiments when steps 312 and 314 are performed, a force (e.g., force 132 of FIG. 2E) is applied to the combined wafer (e.g., combined wafer 114 of FIG. 2E) to separate the first device wafer (e.g., integrated circuit wafer 100 of FIG. 2E) into a plurality of dies (e.g., dies 122A-122D of FIG. 2E) as described above with reference to FIG. 2E.

In step 320, in some embodiments when steps 312 and 314 are omitted, the first protective coating (e.g., protective coating 116 of FIG. 1K) is removed as described above with reference to FIG. 1L. In some embodiments when steps 312 and 314 are performed, the first protective coating (e.g., protective coating 116 of FIG. 2E) is removed as described above with reference to FIG. 2F.

In step 322, in some embodiments when steps 312 and 314 are omitted, one or more of the plurality of dies (e.g., dies 122A-122C of FIG. 1M) are bonded to a second device wafer as described above with reference to FIG. 1M. In some embodiments when steps 312 and 314 are performed, one or more of the plurality of dies (e.g., dies 122A-122C of FIG. 2G) are bonded to a second device wafer as described above with reference to FIG. 2G.

In step 324, in some embodiments when steps 312 and 314 are omitted, singulated portions of the temporary wafer (e.g., temporary regions 112A-112C of FIG. 1N) are de-bonded from the one or more bonded dies (e.g., dies 122A-122C of FIG. 1N) as described above with reference to FIGS. 1N and 1O. In some embodiments when steps 312 and 314 are performed, singulated portions of the temporary wafer (e.g., temporary regions 112A-112C of FIG. 2H) are de-bonded from the one or more bonded dies (e.g., dies 122A-122C of FIG. 2H) as described above with reference to FIGS. 2H and 2I.

Example embodiments of the disclosure are described below. Other embodiments can also be understood from the entirety of the specification as well as the claims filed herein.

Example 1. A method including receiving a first device wafer, which comprises a plurality of dies. The method further includes bonding a first side of a temporary wafer to a first side of the first device wafer to form a combined wafer and performing a first patterning process on the combined wafer to form a plurality of first trenches in the combined wafer. The plurality of first trenches fully extend through the first device wafer and partially into the temporary wafer from the first side of the temporary wafer. The plurality of first trenches separate the plurality of dies from each other. The method further includes placing the combined wafer on a support with the temporary wafer being interposed between the support and the first device wafer and applying a force to the combined wafer to separate the temporary wafer into individual temporary regions. Each individual temporary region is bonded to a respective individual die. The method further includes attaching individual dies to a second device wafer and removing the individual temporary regions from the individual dies.

Example 2. The method of example 1, where the first patterning process includes a laser etching process, a plasma etching process, or a mechanical dicing process.

Example 3. The method of one of examples 1 and 2, where the temporary wafer includes a quartz wafer or a semiconductor wafer.

Example 4. The method of one of examples 1 to 3, where the plurality of first trenches are formed in scribe lines of the first device wafer.

Example 5. The method of one of examples 1 to 4, further including, before placing the combined wafer on the support, performing a second patterning process on the combined wafer to form a plurality of second trenches in the combined wafer, the plurality of second trenches partially extending into the temporary wafer from a second side of the temporary wafer, the plurality of second trenches being vertically aligned with the plurality of first trenches.

Example 6. The method of one of examples 1 to 5, where the second patterning process includes a plasma etching process.

Example 7. The method of one of examples 1 to 6, where: the first side of the temporary wafer is bonded to the first side of the first device wafer using a temporary bonding layer; and removing the individual temporary regions from the individual dies includes subjecting the temporary bonding layer to a radiation.

Example 8. A method including receiving a first device wafer. The first device wafer includes a plurality of dies separated by scribe lines. The method further includes bonding a first side of a temporary wafer to a first side of the first device wafer using a temporary bonding layer to form a combined wafer and thinning a second side of the first device wafer. The second side of the first device wafer is opposite to the first side of the first device wafer. The method further includes depositing a first protective coating on the second side of the first device wafer and performing a first patterning process on the combined wafer to form a plurality of first trenches in the combined wafer. The plurality of first trenches fully extending through the first protective coating and the first device wafer, and partially into the temporary wafer from the first side of the temporary wafer. The plurality of first trenches are formed in the scribe lines. The method further includes placing the combined wafer on a support with the temporary wafer being interposed between the support and the first device wafer and applying a force to the combined wafer to mechanically separate the temporary wafer into individual temporary regions. Each individual temporary region is bonded to a respective individual die. The method further includes bonding individual dies to a second device wafer and de-bonding the individual temporary regions from the individual dies.

Example 9. The method of example 8, where de-bonding the individual temporary regions from the individual dies includes subjecting the temporary bonding layer to an electromagnetic radiation.

Example 10. The method of one of examples 8 and 9, where the first patterning process includes a laser etching process, a plasma etching process, or a mechanical dicing process.

Example 11. The method of one of examples 8 to 10, where the temporary wafer includes a quartz wafer or a semiconductor wafer.

Example 12. The method of one of examples 8 to 11, where, before placing the combined wafer on the support, the method further includes: depositing a second protective coating on a second side of the temporary wafer, where the second side of the temporary wafer is opposite to the first side of the temporary wafer; and performing a second patterning process on the combined wafer to form a plurality of second trenches in the combined wafer, the plurality of second trenches fully extending through the second protective coating and partially into the temporary wafer from the second side of the temporary wafer, the plurality of second trenches being vertically aligned with the plurality of first trenches.

Example 13. The method of one of examples 8 to 12, where the second patterning process includes a plasma etching process.

Example 14. The method of one of examples 8 to 13, where bonding the individual dies to the second device wafer includes direct bonding the individual dies to the second device wafer.

Example 15. A method including receiving a first device wafer. The first device wafer includes a plurality of dies separated by scribe lines. The method further includes bonding a first side of a temporary wafer to a first side of the first device wafer using a temporary bonding layer to form a combined wafer, reducing a thickness of the first device wafer, and depositing a first protective coating on a second side of the first device wafer. The second side of the first device wafer is opposite to the first side of the first device wafer. The method further includes forming a plurality of first trenches in the scribe lines of the first device wafer. The plurality of first trenches fully extend through the first protective coating and the first device wafer, and separate the plurality of dies from each other. The method further includes partially extending the plurality of first trenches into the temporary wafer and depositing a second protective coating on a second side of the temporary wafer. The second side of the temporary wafer is opposite to the first side of the temporary wafer. The method further includes forming a plurality of second trenches in the temporary wafer. The plurality of second trenches fully extend through the second protective coating and partially into the temporary wafer from the second side of the temporary wafer. The plurality of second trenches being vertically aligned with the plurality of first trenches. The method further includes placing the combined wafer on a support with the temporary wafer being interposed between the support and the first device wafer and applying a force to the combined wafer to separate the temporary wafer into individual temporary regions. Each individual temporary region is bonded to a respective individual die. The method further includes bonding individual dies to a second device wafer, and de-bonding the individual temporary regions from the individual dies.

Example 16. The method of example 15, where de-bonding the individual temporary regions from the individual dies includes subjecting the temporary bonding layer to a laser radiation.

Example 17. The method of one of examples 15 and 16, where forming the plurality of first trenches includes a laser etching process, a plasma etching process, or a mechanical dicing process.

Example 18. The method of one of examples 15 to 17, where the temporary wafer includes a quartz wafer or a semiconductor wafer.

Example 19. The method of one of examples 15 to 18, where forming the plurality of second trenches includes a plasma etching process.

Example 20. The method of one of examples 15 to 19, where bonding the individual dies to the second device wafer includes direct bonding the individual dies to the second device wafer.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the disclosure. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

While this disclosure has been described with reference to illustrative embodiments, this description is not intended to be construed in a limiting sense. Various modifications and combinations of the illustrative embodiments, as well as other embodiments of the disclosure, will be apparent to persons skilled in the art upon reference to the description. It is therefore intended that the appended claims encompass any such modifications or embodiments.

What is claimed is:

1. A method comprising:
receiving a first device wafer, the first device wafer comprising a plurality of dies;
bonding a first side of a temporary wafer to a first side of the first device wafer to form a combined wafer;
performing a first patterning process on the combined wafer to form a plurality of first trenches in the combined wafer, the plurality of first trenches fully extending through the first device wafer and partially into the temporary wafer from the first side of the temporary wafer, the plurality of first trenches separating the plurality of dies from each other;
placing the combined wafer on a support with the temporary wafer being interposed between the support and the first device wafer;
applying a force to the combined wafer to separate the temporary wafer into individual temporary regions, each individual temporary region being bonded to a respective individual die;
attaching individual dies to a second device wafer; and
removing the individual temporary regions from the individual dies.

2. The method of claim 1, wherein the first patterning process comprises a laser etching process, a plasma etching process, or a mechanical dicing process.

3. The method of claim 1, wherein the temporary wafer comprises a quartz wafer or a semiconductor wafer.

4. The method of claim 1, wherein the plurality of first trenches are formed in scribe lines of the first device wafer.

5. The method of claim 1, further comprising, before placing the combined wafer on the support, performing a second patterning process on the combined wafer to form a plurality of second trenches in the combined wafer, the plurality of second trenches partially extending into the temporary wafer from a second side of the temporary wafer, the plurality of second trenches being vertically aligned with the plurality of first trenches.

6. The method of claim 5, wherein the second patterning process comprises a plasma etching process.

7. The method of claim 1, wherein:
the first side of the temporary wafer is bonded to the first side of the first device wafer using a temporary bonding layer; and
removing the individual temporary regions from the individual dies comprises subjecting the temporary bonding layer to a radiation.

8. A method comprising:
receiving a first device wafer, the first device wafer comprising a plurality of dies separated by scribe lines;
bonding a first side of a temporary wafer to a first side of the first device wafer using a temporary bonding layer to form a combined wafer;
thinning a second side of the first device wafer, wherein the second side of the first device wafer is opposite to the first side of the first device wafer;
depositing a first protective coating on the second side of the first device wafer;
performing a first patterning process on the combined wafer to form a plurality of first trenches in the combined wafer, the plurality of first trenches fully extending through the first protective coating and the first device wafer, and partially into the temporary wafer from the first side of the temporary wafer, the plurality of first trenches being formed in the scribe lines;
placing the combined wafer on a support with the temporary wafer being interposed between the support and the first device wafer;
applying a force to the combined wafer to mechanically separate the temporary wafer into individual temporary regions, each individual temporary region being bonded to a respective individual die;
bonding individual dies to a second device wafer; and
de-bonding the individual temporary regions from the individual dies.

9. The method of claim 8, wherein de-bonding the individual temporary regions from the individual dies comprises subjecting the temporary bonding layer to an electromagnetic radiation.

10. The method of claim 8, wherein the first patterning process comprises a laser etching process, a plasma etching process, or a mechanical dicing process.

11. The method of claim 8, wherein the temporary wafer comprises a quartz wafer or a semiconductor wafer.

12. The method of claim 8, wherein before placing the combined wafer on the support, the method further comprises:
depositing a second protective coating on a second side of the temporary wafer, wherein the second side of the temporary wafer is opposite to the first side of the temporary wafer; and
performing a second patterning process on the combined wafer to form a plurality of second trenches in the combined wafer, the plurality of second trenches fully extending through the second protective coating and partially into the temporary wafer from the second side of the temporary wafer, the plurality of second trenches being vertically aligned with the plurality of first trenches.

13. The method of claim 12, wherein the second patterning process comprises a plasma etching process.

14. The method of claim 12, wherein bonding the individual dies to the second device wafer comprises direct bonding the individual dies to the second device wafer.

15. A method comprising:
receiving a first device wafer, the first device wafer comprising a plurality of dies separated by scribe lines;
bonding a first side of a temporary wafer to a first side of the first device wafer using a temporary bonding layer to form a combined wafer;
reducing a thickness of the first device wafer;
depositing a first protective coating on a second side of the first device wafer, wherein the second side of the first device wafer is opposite to the first side of the first device wafer;
forming a plurality of first trenches in the scribe lines of the first device wafer, the plurality of first trenches fully extending through the first protective coating and the first device wafer, and separating the plurality of dies from each other;
partially extending the plurality of first trenches into the temporary wafer;
depositing a second protective coating on a second side of the temporary wafer, wherein the second side of the temporary wafer is opposite to the first side of the temporary wafer;
forming a plurality of second trenches in the temporary wafer, the plurality of second trenches fully extending through the second protective coating and partially into the temporary wafer from the second side of the temporary wafer, the plurality of second trenches being vertically aligned with the plurality of first trenches;
placing the combined wafer on a support with the temporary wafer being interposed between the support and the first device wafer;
applying a force to the combined wafer to separate the temporary wafer into individual temporary regions, each individual temporary region being bonded to a respective individual die;
bonding individual dies to a second device wafer; and
de-bonding the individual temporary regions from the individual dies.

16. The method of claim 15, wherein de-bonding the individual temporary regions from the individual dies comprises subjecting the temporary bonding layer to a laser radiation.

17. The method of claim 15, wherein forming the plurality of first trenches comprises a laser etching process, a plasma etching process, or a mechanical dicing process.

18. The method of claim 15, wherein the temporary wafer comprises a quartz wafer or a semiconductor wafer.

19. The method of claim 15, wherein forming the plurality of second trenches comprises a plasma etching process.

20. The method of claim 15, wherein bonding the individual dies to the second device wafer comprises direct bonding the individual dies to the second device wafer.
